(19) United States
(12) Patent Application Publication
(10) Pub. No.: US 2025/0275261 A1
(43) Pub. Date: Aug. 28, 2025

(54) AVALANCHE PHOTODETECTORS FOR PARALLEL OPTICAL INTERCONNECTS

(71) Applicants: Sarah Zou, Sunnyvale, CA (US); Alexander Tselikov, Sunnyvale, CA (US); Robert Kalman, Sunnyvale, CA (US); Bardia Pezeshki, Sunnyvale, CA (US)

(72) Inventors: Sarah Zou, Sunnyvale, CA (US); Alexander Tselikov, Sunnyvale, CA (US); Robert Kalman, Sunnyvale, CA (US); Bardia Pezeshki, Sunnyvale, CA (US)

(21) Appl. No.: 19/064,645

(22) Filed: Feb. 26, 2025

Related U.S. Application Data
(60) Provisional application No. 63/557,823, filed on Feb. 26, 2024.
(60) Provisional application No. 63/568,800, filed on Mar. 22, 2024.

(51) Int. Cl. H10F 30/225; H10F 77/1226; H10F 77/20

(52) U.S. Cl. CPC H10F 30/225; H10F 77/1227; H10F 77/206

(57) ABSTRACT

A lateral photodetector may include a high e-field multiplication region. The high e-field multiplication region may be provided by lightly p doping areas adjacent to or near an n-finger of the photodetector. The high e-field multiplication region may also be provided by providing a slightly conducting horizontal plane between p-fingers and n-fingers of the photodetector. The photodetector may be grown on a silicon substrate, which is etched to form a gap to allow for light to reach the photodetector through the gap.

### CROSS-REFERENCE TO RELATED APPLICATIONS

This application claims the benefit of U.S. Provisional Patent Application Nos. 63/557,823, filed on Feb. 26, 2024, and 63/568,800, filed on Mar. 22, 2024, the disclosures of which are incorporated by reference herein.

### BACKGROUND OF THE INVENTION

Information flow between integrated circuits, processors, and memory is currently the bottleneck for many computing and, especially, Machine Learning or Artificial Intelligence applications. Advances in semiconductors have shrunk the size of transistors allowing massive integration, however, comparatively little progress has been made in improving the bandwidth of communication across a chip or between chips. Optical interconnection techniques have long been seen as the solution, providing lower power and denser connections than copper wiring, but the complexities of integrating lasers on silicon chips or connecting large numbers of fibers to chips has precluded practical application of optical interconnects using standard laser or silicon photonics technologies.

Recently, there have been exciting demonstrations of optical interconnects between chips using arrays of microLEDs that are transferred onto silicon substrates. These LEDs can modulate at rates exceeding 10 Gb/s and are paired with silicon photodetectors on the other side of an optical link. Operating at short wavelengths (˜450 nm), they leverage display technology and can form large arrays. This enables parallel communication between chips at very low power and high density. FIG. 1 shows a diagram of such a parallel approach. An array of hundreds, thousands, or more LEDs 111 are combined with drivers 113 in a CMOS chip. The LEDs are generally fabricated out of GaN material and are transferred onto silicon chips directly on top of the driver. Each LED has its own driver beneath it. Parallel data lines 115 feed these LED drivers that modulate the LEDs with on-off patterns. Using imaging fiber 117, bundles of lighting fiber, or even lenses for free space imaging, the LED array is optically connected to a detector array. Each detector 119 has its own amplifier (TIA—transimpedance amplifier) 121, and regenerates the electrical data lines 123.

### BRIEF SUMMARY OF THE INVENTION

Some aspects of the invention provide a lateral interdigitated photodetector, comprising: an n-doped finger; a p-doped finger; a silicon light absorption layer at least between the n-doped finger and the p-doped finger; with the lateral photodetector configured to have a high electric field about the n-doped finger and between the n-doped finger and p-doped finger. In some aspects the lateral photodetector is configured to have the high electric field about the n-doped finger and between the n-doped finger and p-doped finger by way of a vertical ground along a horizontal plane between the n-doped finger and the p-doped finger. In some aspects the lateral photodetector is configured to have the high electric field about the n-doped finger and between the n-doped finger and p-doped finger by way of a conductive layer under the silicon light absorption layer. In some aspects the conductive layer is provided by a p-type conductive layer. In some aspects the lateral photodetector is configured to have the high electric field about the n-doped finger and between the n-doped finger and p-doped finger by way of a p-type implant about the n-doped finger. In some aspects the p-type implant is spaced a predetermined distance from the n-doped finger. In some aspects the p-type implant is adjacent to the n-doped finger. In some aspects the lateral photodetector is on an oxide layer supported at least in part by a silicon layer. In some aspects the lateral photodetector allows for back illumination by the silicon layer including a gap allowing for passage of light through the oxide layer to the silicon light absorption layer.

Some aspects of the invention provide an integrated circuit chip and a photodetector array chip mounted thereon, the photodetector chip comprising a lateral photodetector comprising: an n-doped finger; a p-doped finger; a silicon light absorption layer at least between the n-doped finger and the p-doped finger; with the lateral photodetector configured to have a high electric field about the n-doped finger and between the n-doped finger and p-doped finger; and an oxide layer on a side of the silicon light absorption layer facing away from the integrated circuit chip. Some aspects further comprise a silicon layer on the oxide layer. In some aspects the silicon layer includes a gap allowing for passage of light through the oxide layer to the silicon light absorption layer so as to allow for back illumination of the lateral photodetector. In some aspects the lateral photodetector is configured to have the high electric field about the n-doped finger and between the n-doped finger and p-doped finger by way of a vertical ground along a horizontal plane between the n-doped finger and the p-doped finger. In some aspects the lateral photodetector is configured to have the high electric field about the n-doped finger and between the n-doped finger and p-doped finger by way of a conductive layer under the silicon light absorption layer. In some aspects the conductive layer is provided by a p-type conductive layer. In some aspects the lateral photodetector is configured to have the high electric field about the n-doped finger and between the n-doped finger and p-doped finger by way of a p-type implant about the n-doped finger. In some aspects the p-type implant is spaced a predetermined distance from the n-doped finger. In some aspects the p-type implant is adjacent to the n-doped finger. Some aspects further comprise a microLED array, bonded to the integrated circuit chip.

These and other aspects of the invention are more thoroughly comprehended upon review of this disclosure.

### BRIEF DESCRIPTION OF THE FIGURES

FIG. 1 shows a parallel optical communications approach using microLEDs and photodetectors.

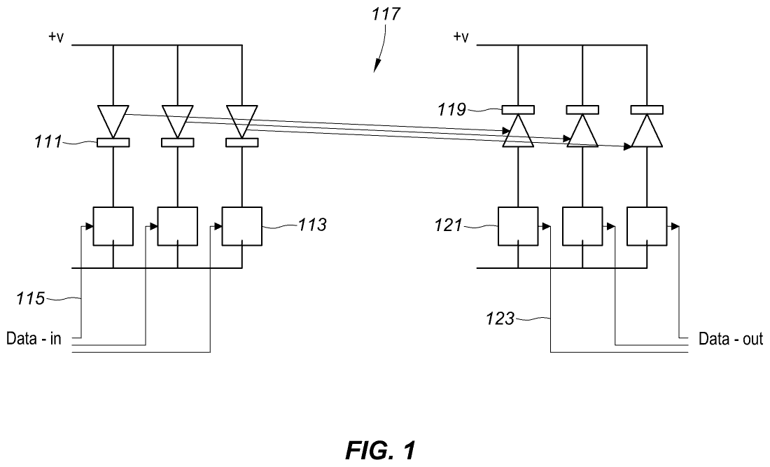

FIGS. 2a,b show two basic approaches for detectors in or on a CMOS silicon chip

FIGS. 3a-i show a process flow in which a detecting region is fabricated adjacent to

transistors.

FIGS. 4a,b show the interdigitated fingers of the lateral photodetector.

FIG. 5 shows a chip that uses the adjacent photodetector design of FIG. 2a

FIGS. 6a-d show aspects of a transceiver integrated circuit with detectors on top of

amplifiers.

FIG. 7 shows a cross-sectional representation of portions of a lateral photodetector.

FIG. 8 shows a cross-sectional representation of portions of a further lateral photodetector.

FIGS. 9a,b illustrate cross-sections of vertical photodetectors.

FIG. 10 is a cross-section of a still further lateral photodetector.

FIG. 11 is a cross-section of a yet still further lateral photodetector.

FIG. 12 shows a chart of implant depths for a first example for doping of the n-finger and the lightly doped p-finger.

FIGS. 13a,b show an E-field and voltage for a device with the doping of FIG. 12.

FIG. 14 shows a chart of implant depths for a second example for doping of the n-finger and the lightly doped p-finger.

FIGS. 15a,b show an E-field and voltage for a device with the doping of FIG. 14.

### DETAILED DESCRIPTION

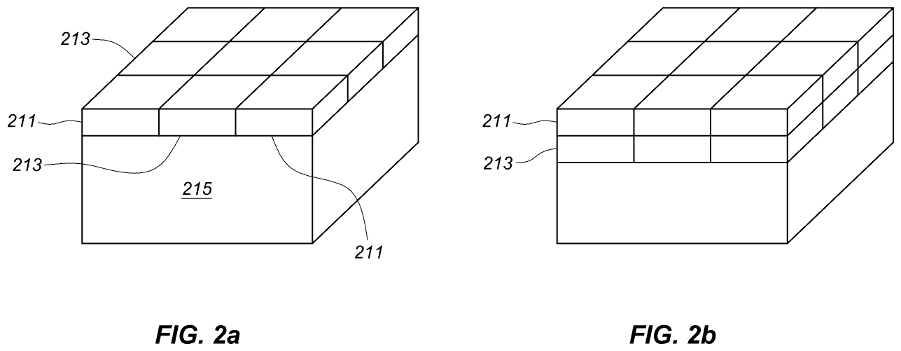

The LEDs are generally transferred to the CMOS silicon chip using display technology, but at these short wavelengths, one has a variety of options for the receiver. FIGS. 2a,b show two basic approaches for detectors in or on a CMOS silicon chip. Silicon absorbs short wavelength light readily, with an absorption depth of a few tenths of a micron. Thus, as illustrated in FIG. 2a, one can make a detector structure 211 in a CMOS silicon chip 215 itself. Each detector is then connected to an adjacent corresponding amplifier 213. Alternatively, the detecting region can be made vertically above the amplifier array as shown in FIG. 2b. In such embodiments the detector array may be fabricated and then attached to the silicon chip. This can be done individually for each detector, such as is generally done for the LEDs, or an entire array of detectors can be bonded simultaneously using standard soldering techniques, or an entire wafer can be bonded using hybrid bonding, then thinned. This last technique is generally used for cameras or CMOS imagers. In all these cases, the detecting region is usually above the chip with the amplifiers and potential digital circuitry.

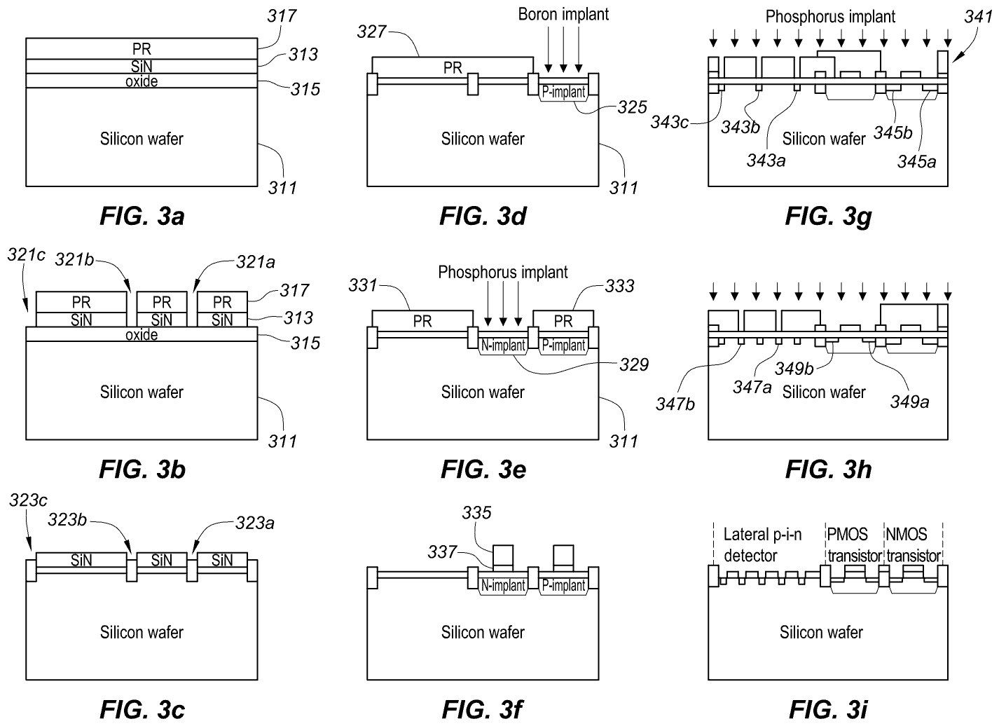

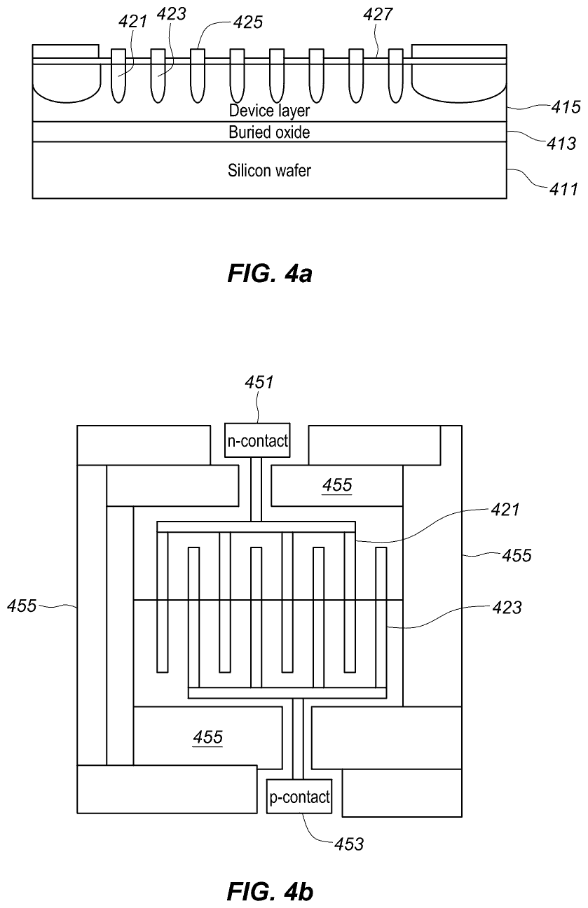

FIGS. 3a-i show a process flow in which a detecting region is fabricated adjacent to transistors, for example of an amplifier, as in the example of FIG. 2a. Generally p-well and n-wells are made first. Then source and drains implants are performed. The detector comprises, and in some embodiments consists of, a lateral p-i-n section that uses the source and drain implants to form the p and n regions. These p and n regions form interdigitated fingers as shown in a top view shown in FIG. 4a. One generally does not want a p or n well around the detector as having low background doping is often desired for photodetectors to lower the operating and allow a large depletion region for the absorption of light. FIGS. 4a,b show the interdigitated fingers of the lateral photodetector. In this example, an SOI wafer is used that has many advantages.

In more detail, like a normal CMOS process, the process begins with a lightly doped silicon wafer 311 with a silicon nitride (SiN) top coating 313 on a thin layer of oxide 315, as illustrated in FIG. 3a. FIG. 3a also shows a photoresist layer 317 on top of the SiN top coating. The silicon nitride layer is patterned 321a-c with the photoresist and etched, down to the oxide layer as shown in FIG. 3b. An oxidation step using a local oxidation of silicon (LOCOS) process causes the exposed areas to have much thicker oxide 323a-c, that provides increased isolation between the different areas of the device, as shown in FIG. 3c. A p-type implant, for example a boron implant, is provided to form P-wells 325 of the NMOS regions. Photoresist 327 is used to block a p-type implant, for example so that the implant is only allowed to penetrate the wafer where NMOS transistors are formed, as shown in FIG. 3d. The process is repeated with an N-type implant, for example a phosphorous implant, to form the N-wells 329 of the PMOS regions, with photoresist 331, 333 used to block the n-type implant, for example as shown in FIG. 3e. Note that both these implants are blocked by photoresist 327 and 331 in a photodetector region.

Then a polysilicon layer 337 is deposited and patterned by photoresist 335 and etched to form the gate oxide, for example as shown in FIG. 3f. Gates are used for both the PMOS and NMOS regions, but all the polysilicon is removed from the detector region. The wafer is then patterned again with photoresist 341 to block an n-type implant, for example a phosphorous implant, on the PMOS transistor, while the polysilicon blocks the implant around the gate and drain regions of the NMOS transistor in a self-aligned process. In the detector region, the photoresist is patterned to form openings for the n-fingers of the lateral p-i-n photodetector. The n-type implant forms the source and drain regions 345a,b of the NMOS transistor and at the same time forms the n+ regions 343a-c of the photodetector, for example as shown in FIG. 3g. A similar process is used for a p-type implant, such as Boron, to form source and drain contacts 349a,b of the PMOS transistor and at the same time form the p+ regions 347a,b of the photodetector, for example as shown in FIG. 3h. With the source and drain regions of the transistors formed in the same manner as the p+ and n+ regions of the photodetector, the source and drain regions of the transistors have a similar implant depth as the p+ and n+ regions of the photodetector. Any remaining photoresist is removed, resulting in a lateral p-i-n detector adjacent a PMOS and NMOS transistor, for example as shown in FIG. 3i.

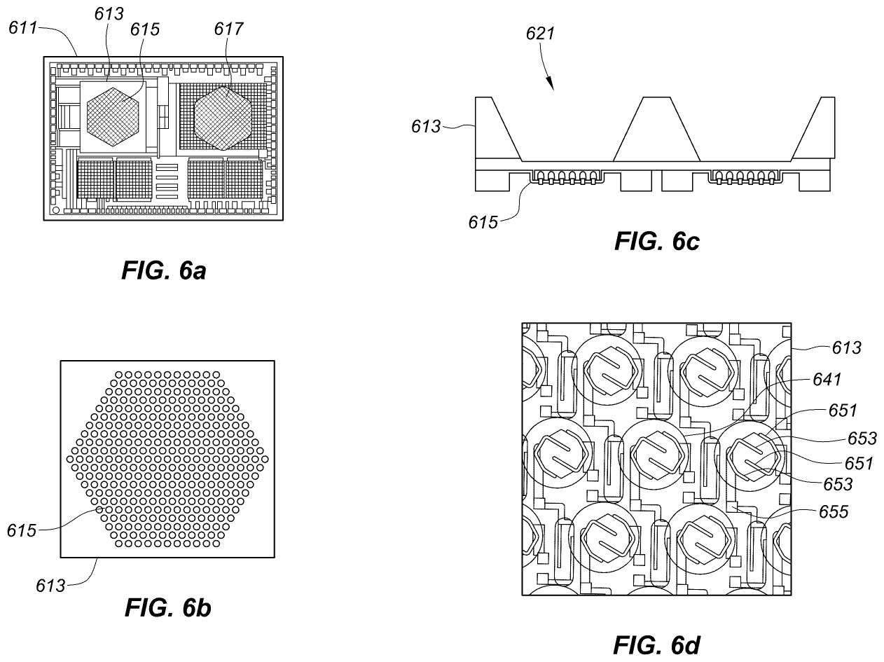

FIG. 4a shows a vertical structure and FIG. 4b shows a top view of example interdigitated contacts of p+ and n+ with lightly doped semiconductor in between. As may be seen in FIG. 4a, a silicon wafer 411 includes a device layer 415 about its upper portion. The device layer includes n-fingers 421 interspersed with p-fingers 423. The n-fingers may be made at the same time as source and drain contacts of an NMOS transistor, for example as discussed with respect to FIGS. 3a-i. Similarly, the p-fingers may be made at the same time as source and drain contacts of a PMOS transistor, also for example as discussed with respect to FIGS. 3a-i. The n-fingers and the p-fingers are part of a lateral p-i-n photodetector. Although FIG. 4b shows the n-fingers and the p-fingers extending into the device or active layer but not reaching the buried oxide layer, in some embodiments the p-fingers and/or the n-fingers may extend down to the buried oxide layer. In some embodiments the active layer may be 0.135 um, and the buried oxide layer may be 0.5 um. In some embodiments the buried oxide layer may be omitted, for example in embodiments in which a chip with photodetectors is mounted upside down on another chip, for example as discussed with respect to FIGS. 6a-d. In such embodiments, the region shown as a buried oxide layer in FIG. 4a may instead be a SiO2 layer, or other a layer of other material transparent to light, particularly light at a wavelength of interest. In many cases, the uLEDs emit light with a wavelength of about 450 nm, and 450 nm is the wavelength of interest. The p-fingers are connected to a p-contact 453, and the n-fingers are connected to an n-contact 451. In some embodiments, areas between the fingers may have an anti-reflective coating 427, for example an oxide anti-reflective coating. Any light that falls on the fingers does not generate a photocurrent. If the fingers are metalized 425, this is because the light is reflected or absorbed by the metal.

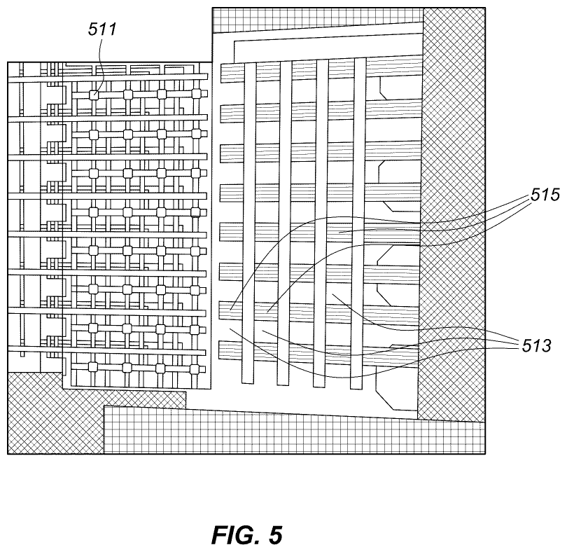

FIG. 5 shows a chip that uses the adjacent photodetector design of FIG. 2a. The chip is fabricated on a 130 nm silicon on insulator (SOI) process. On the left hand side of the die are 32 GaN LEDs 511 that are mounted on driver circuitry. On the right hand side are the lateral p-i-n photodetectors 513 that are adjacent to the amplifiers 515 in a grid format. The detectors are formed from the source and drain implants of the transistors, for example as described in FIGS. 3a-i.

Alternatively, one can mount the detectors on top of the amplifiers, for example as described in FIG. 2b. FIGS. 6a-d show aspects of a transceiver integrated circuit with detectors on top of amplifiers. The integrated circuit is fabricated in 16 nm FinFET process. This advanced process does not make low doped silicon material readily available at the surface for the fabrication of photodetectors. Thus, as may be seen in FIG. 6a, a separate photodetector array chip 613 was fabricated and mounted upside down on a chip 611, with the photodetector array 615 shown as a hexagonal array. The photodetector chip is shown as adjacent to a microLED array, also bonded to the chip 611. FIG. 6b shows an enlarged view of the photodetector chip 613 and photodetector array 615. FIG. 6c shows a partial cross-sectional view of the photodetector chip, showing two photodetectors, e.g., photodetector 615, of the photodetector array. Made in SOI, it uses the same lateral interdigitated approach outlined previously. However, because the chip is mounted upside down to electrically connect to the TIAs on the chip 611, the back of the chip is etched 621 to allow the light to go through and hit the rear-illuminated photodetectors. This was done with a deep silicon etch to go through the substrate. FIG. 6d is a top view of portions of the detector array. The small squares are the electrical connections to the detectors. The large circles, e.g. circle 641, are the holes in the substrate, visible from the top. The interdigitated fingers 651, 653 are also readily seen.

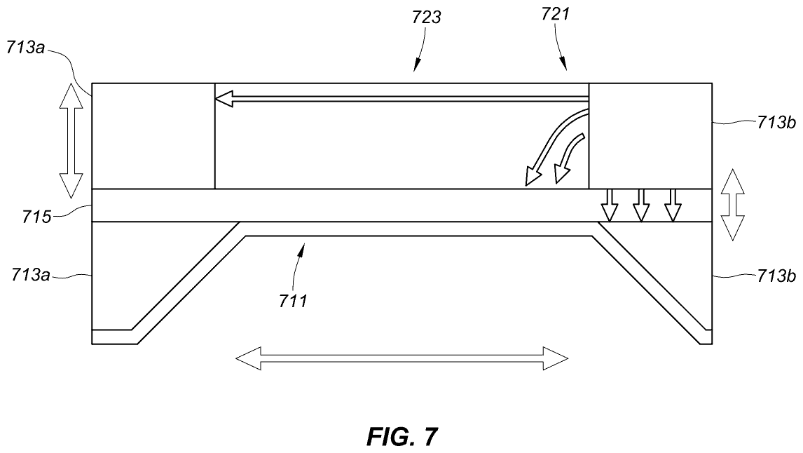

In any detector, to get avalanche multiplication or gain in the device, the electric field generally should approach the breakdown voltage of the semiconductor. In a lateral device where the finger spacing is a few microns, the voltage would nominally have to exceed 100V or so. However, one can obtain avalanche gain in a lateral photodetector because there are also fringing vertical fields. FIG. 7 shows a cross-sectional representation of portions of a lateral photodetector. In FIG. 7, an n-finger 713b is separated from a p-finger 713a by a silicon dielectric layer 712. The silicon dielectric layer may be considered a silicon light absorption layer. The n-finger, p-finger, and silicon dielectric layer may have a depth of 0.5 um. A silicon dioxide layer 715 underlays the silicon dielectric layer. As illustrated the silicon dioxide layer also underlays the p-finger and the n-finger. In some embodiments the silicon dielectric layer has a greater dielectric constant than the dielectric constant of the silicon dioxide layer. In some embodiments the dielectric constant of the silicon dielectric layer is three times the dielectric constant of the silicon dioxide layer. A thin indium-tin-oxide layer (ITO) 711 is placed on the rear of the photodetector, under the silicon dioxide layer and generally in a horizontal plane, to provide a vertical ground. The presence of the vertical ground results in a high electric field region 721 in the silicon dielectric layer about the n-finger, and a generally uniform low electric field elsewhere in the silicon dielectric layer. The vertical ground provided by the ITO brings down the voltage needed for avalanche multiplication and in fact brings about a softer breakdown as the high field region is relatively small. Carriers are generated along the depletion region between the fingers. Ideally the p-finger is grounded as is the back conductor (such as ITO). As the electrons move towards the n-finger, many of them enter the high field fringing field region and multiply, increasing the photocurrent. Some of the holes do build up along the silicon dioxide layer, but slowly drift to the p-finger over time.

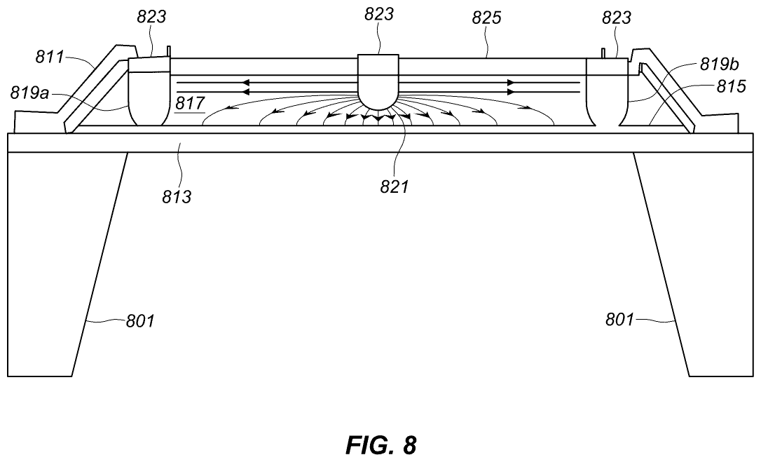

The design of the avalanche photodetector in FIG. 7 can be improved, if a thin conductive layer exists next to the oxide, to facilitate the movement of holes to the p-finger and prevent a charge build up against the oxide. This is shown in the cross-section of FIG. 8. In this case the SOI wafer has a thin p-type conductive layer 815 above the oxide 813. Low doped silicon 817 is then epitaxially grown over this oxide, and the same lateral fingers are fabricated. In FIG. 8, p-fingers 819a,b are on opposing sides of the dielectric layer 817. An n-finger 821 is located between the p-fingers. An oxide 825 may be grown over the dielectric layer, for example to provide insulation for contacts 811 to the p-fingers. The p-fingers and n-fingers may have metallizations 823. In some embodiments it may be desirable that this lower conductive layer 815 be thin for two reasons. First, light, traversing the etched away portion of the silicon substrate 801 underlying the oxide 813, must generally penetrate this layer to enter the undoped and high field region. Any light that is absorbed in this layer with very little electric field does not generate photocurrent and thus reduces the efficiency of the detector. Also, this layer can form a parallel plate capacitor with the n-finger. The capacitance, however, does not slow down the detector if the resistance of the layer is high enough. Nominal design values are 50 nm thickness for the conductive p-layer, doped about 1E18/cm\hat{ }3, the thickness of the silicon is about 1 micron, and the finger spacing between p and n fingers is about 2 to 5 microns.

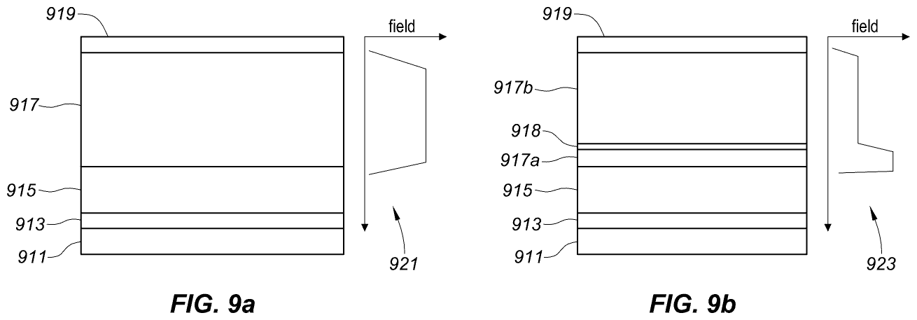

Rather than lateral p-i-n structures, one may also use vertical detectors. FIG. 9a shows a top illuminated vertical detector, along with an associated electric field corresponding to depth within the vertical detector. The vertical detector of FIG. 9a has a thin p-region 919 on top, a low doped intrinsic region 917, which can be grown through silicon epitaxy, and a buried n-region 915. This can be made in SOI or in bulk silicon. FIG. 9a shows the n-region as being on a silicon dioxide layer 913, which in turn is on a silicon substrate 911.

In a p-i-n diode, the electric field builds up in the depletion region of the p and n and is constant in the depletion region. Similar to a previous case, the top p-doped layer is relatively thin as there is no electric field in conductive layers. However, doping may be high, ideally above 1E19/cm\hat{ }3, to provide a good electrical connection to the diode. In some embodiments, for a 30 micron diameter diode to have less than 30 fF capacitance, the intrinsic region is greater than about 3 microns thick. This gives a 3 dB transit time>10 GHz, and speed saturates at about 6V, with breakdown at about 90V. Avalanche multiplication would be about 40V to start.

A much lower voltage vertical diode can be made by having a thin breakthrough region close to the n-contact. This is shown in the vertical detector of FIG. 9b. The vertical detector of FIG. 9b is similar to that of FIG. 9a, except the region 917 is split into two regions 917a,b, separated by a thin p-region 918 close to the buried n-region. The electric field increases between the totally depleted p+ region and the n-contact. Moreover, having the breakthrough region close to the n-region, but separated from the n-region by some of the intrinsic region, may allow for avalanche multiplication with voltages further below device breakdown voltages than would be the case if the breakthrough region was immediately adjacent the n-region. Thus avalanche multiplication voltage can be brought down to 10V or less.

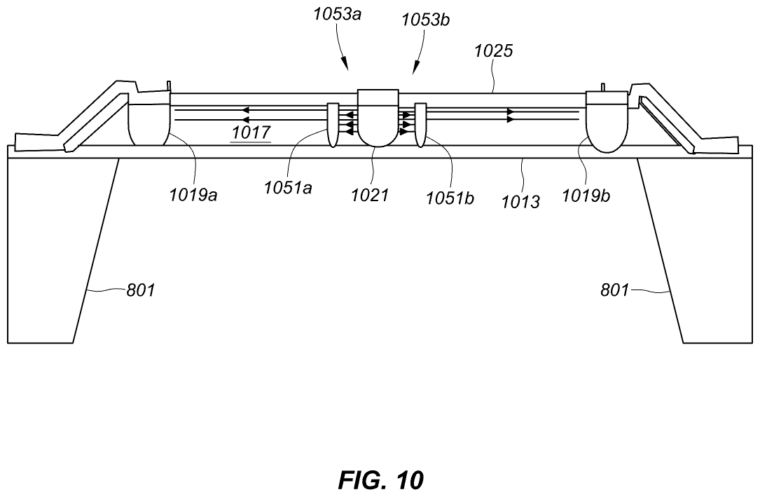

A similar breakthrough region can also be implemented in a lateral structure. This is shown in FIG. 10. FIG. 10 is a cross section of a lateral photodetector, similar to that of FIG. 8. Once again lateral p and n fingers 1019a,b, 1021 are formed in a low doped material 1017. A grown oxide layer 1025 may be over the low doped material. A silicon dioxide layer 1013 underlays the low doped material. Light may reach the low doped material by passing through an etched gap in a silicon substrate 801. However, in the embodiment of FIG. 10, thin p regions 1051a,b are provided on either side and close to the n finger, instead of (or in addition to, in some embodiments) use of the thin p-type conductive layer. In some embodiments the thin p regions are spaced relatively close (<1 um), or in some embodiments 1 um, to the n+ finger. This material is thin enough to become totally depleted, resulting in a high field region 1053a,b around the n+ finger, which can result in avalanche multiplication.

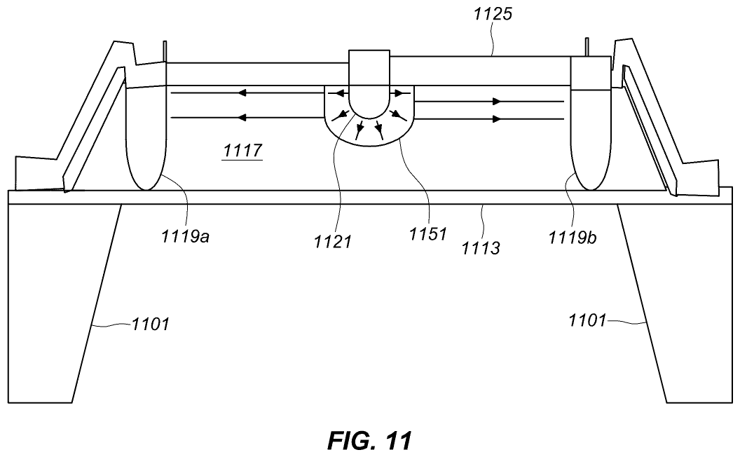

A derivative structure is shown in FIG. 11 and somewhat resembles a SPAD structure (single photon avalanche photodetector). The structure of FIG. 11 is similar to that of FIG. 10, with p fingers 1119a,b on opposite sides of an n finger 1121 and a low doped material 1117 in between. As illustrated, a grown oxide layer 1125 is also over the low doped material. However, in this case, rather than having two separate thin p implants around the n-finger, one makes a somewhat larger, more lightly doped p-finger 1151 around the n-finger. In some embodiments, and as illustrated in FIG. 11, the n-finger may be considered embedded in the lightly doped p-finger, with the lightly doped p-finger and n-finger in contact with one another. This larger lightly doped p-finger gets fully depleted and causes high field regions around the main n-finger, where one can get avalanche multiplication. The overall thickness of silicon can be around 1 micron, sufficient for the short wavelength operation of these detector arrays. Spacing between fingers can be a few microns, and deep trench isolation or opposite implants can be used to isolate these diodes from each other. SOI substrates can be used, and the devices can be operated either with top illumination or rear illumination.

In some embodiments the width of the lightly doped p-finger is 0.1 um, with 1 um spacing between n-finger and p-finger. In some embodiments the lightly doped p-finger around the n-finger has a width or thickness of 0.2 to 0.3 um. In some embodiments the lightly doped p-finger is p-doped after n-doping of the n-finger. A mask used during n-doping of the n-finger may be slightly etched away, leaving a gap exposing areas around the n-finger. The gap (and n-finger) may then be lightly p-doped. The light p-doping lightly dopes the lightly doped p-finger. The light p-doping also somewhat reduces doping levels of the n-finger, but not significantly as the p-doping is lighter than the n-doping.

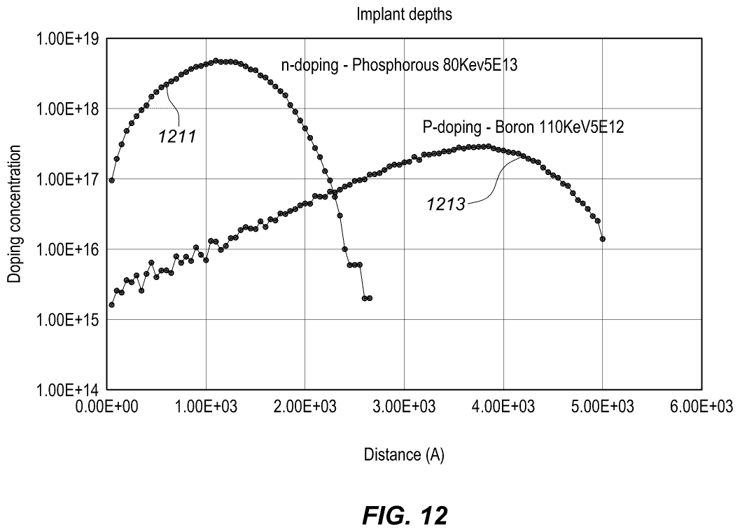

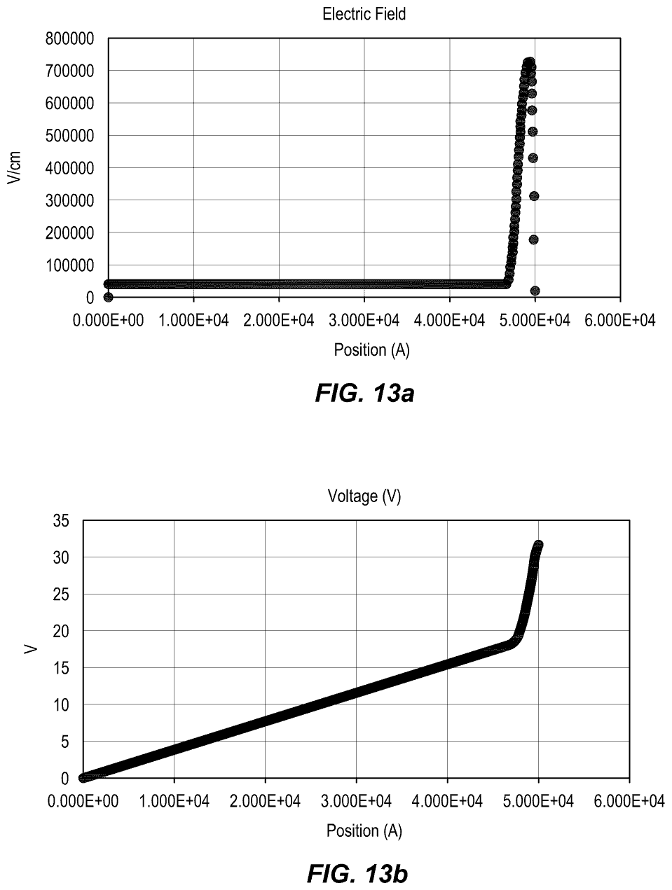

FIG. 12 shows a chart of implant depths for a first example for doping of the n-finger and the lightly doped p-finger. N-doping 1211 for the n-finger has a greater doping concentration than p-doping 1213 for the lightly doped p-finger. The p-doping does have a greater implant depth than the n-doping. The E-field and voltage for a device with the doping of FIG. 12 are shown in FIGS. 13a,b, respectively.

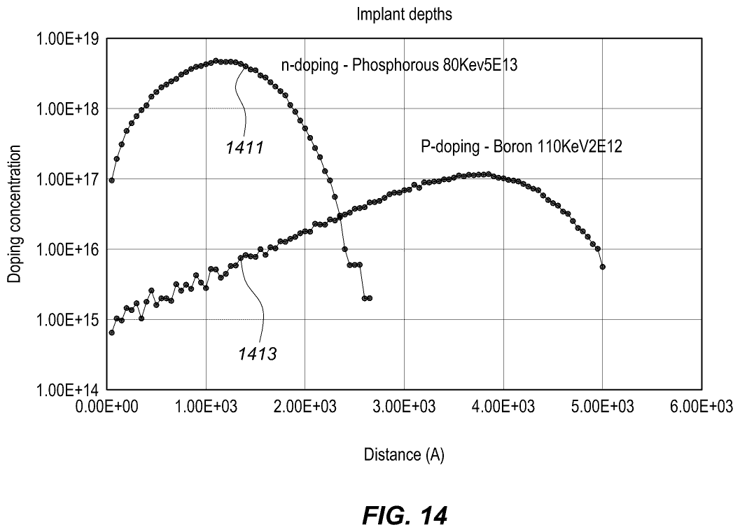

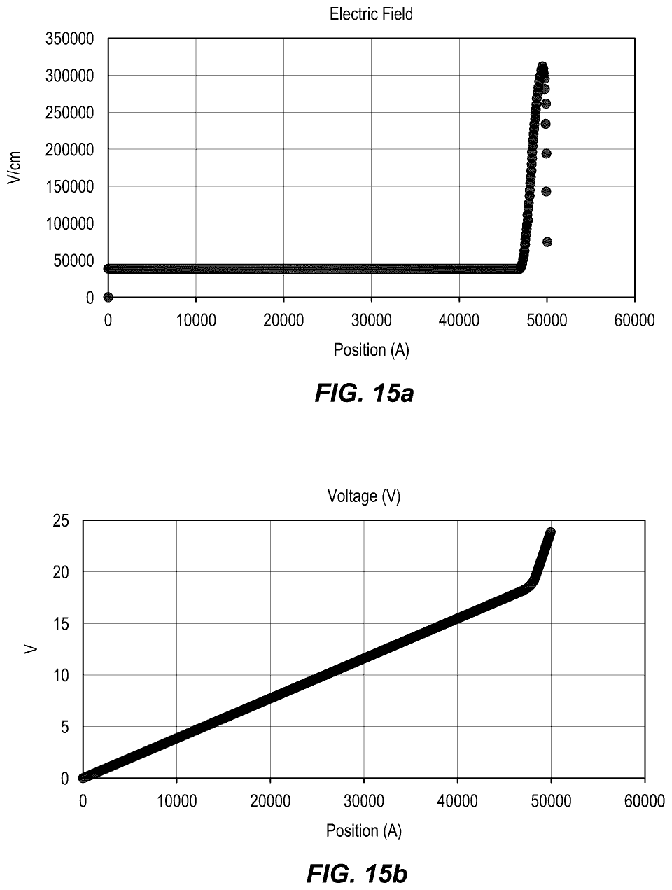

FIG. 14 shows a chart of implant depths for a second example for doping of the n-finger and the lightly doped p-finger. The n-doping 1411 is the same as the n-doping of the example of FIG. 12. The p-doping 1413 is slightly reduced compared to the example of FIG. 12. The E-field and voltage for a device with the doping of FIG. 14 are shown in FIGS. 15a,b, respectively. A comparison of FIGS. 13a,b and FIGS. 15a,b shows that the reduction in p-doping both reduces the maximum electric field and the maximum voltage.

Although the invention has been discussed with respect to various embodiments, it should be recognized that the invention comprises the novel and non-obvious claims supported by this disclosure.

What is claimed is:

1. A lateral interdigitated photodetector, comprising:
an n-doped finger;
a p-doped finger;
a silicon light absorption layer at least between the n-doped finger and the p-doped finger;
with the lateral photodetector configured to have a high electric field about the n-doped finger and between the n-doped finger and p-doped finger.

2. The lateral photodetector of claim 1, wherein the lateral photodetector is configured to have the high electric field about the n-doped finger and between the n-doped finger and p-doped finger by way of a vertical ground along a horizontal plane between the n-doped finger and the p-doped finger.

3. The lateral photodetector of claim 1, wherein the lateral photodetector is configured to have the high electric field about the n-doped finger and between the n-doped finger and p-doped finger by way of a conductive layer under the silicon light absorption layer.

4. The lateral photodetector of claim 3, wherein the conductive layer is provided by a p-type conductive layer.

5. The lateral photodetector of claim 1, wherein the lateral photodetector is configured to have the high electric field about the n-doped finger and between the n-doped finger and p-doped finger by way of a p-type implant about the n-doped finger.

6. The lateral photodetector of claim 5, wherein the p-type implant is spaced a predetermined distance from the n-doped finger.

7. The lateral photodetector of claim 5, wherein the p-type implant is adjacent to the n-doped finger.

8. The lateral photodetector of claim 1, wherein the lateral photodetector is on an oxide layer supported at least in part by a silicon layer.

9. The lateral photodetector of claim 8, wherein the lateral photodetector allows for back illumination by the silicon layer including a gap allowing for passage of light through the oxide layer to the silicon light absorption layer.

10. An integrated circuit chip and a photodetector array chip mounted thereon, the photodetector chip comprising a lateral photodetector comprising:
an n-doped finger;
a p-doped finger;
a silicon light absorption layer at least between the n-doped finger and the p-doped finger;
with the lateral photodetector configured to have a high electric field about the n-doped finger and between the n-doped finger and p-doped finger; and
an oxide layer on a side of the silicon light absorption layer facing away from the integrated circuit chip.

11. The integrated circuit chip and the photodetector array chip mounted thereon of claim 10, further comprising a silicon layer on the oxide layer.

12. The integrated circuit chip and the photodetector array chip mounted thereon of claim 10, wherein the silicon layer includes a gap allowing for passage of light through the oxide layer to the silicon light absorption layer so as to allow for back illumination of the lateral photodetector.

13. The integrated circuit chip and the photodetector array chip mounted thereon of claim 10, wherein the lateral photodetector is configured to have the high electric field about the n-doped finger and between the n-doped finger and p-doped finger by way of a vertical ground along a horizontal plane between the n-doped finger and the p-doped finger.

14. The integrated circuit chip and the photodetector array chip mounted thereon of claim 10, wherein the lateral photodetector is configured to have the high electric field about the n-doped finger and between the n-doped finger and p-doped finger by way of a conductive layer under the silicon light absorption layer.

15. The integrated circuit chip and the photodetector array chip mounted thereon of claim 14, wherein the conductive layer is provided by a p-type conductive layer.

16. The integrated circuit chip and the photodetector array chip mounted thereon of claim 10, wherein the lateral photodetector is configured to have the high electric field about the n-doped finger and between the n-doped finger and p-doped finger by way of a p-type implant about the n-doped finger.

17. The integrated circuit chip and the photodetector array chip mounted thereon of claim 16, wherein the p-type implant is spaced a predetermined distance from the n-doped finger.

18. The integrated circuit chip and the photodetector array chip mounted thereon of claim 16, wherein the p-type implant is adjacent to the n-doped finger.

19. The integrated circuit chip and the photodetector array chip mounted thereon of claim 10, further comprising a microLED array, bonded to the integrated circuit chip.
